(19) United States
(12) Patent Application Publication
(10) Pub. No.: US 2004/0244678 A1
(43) Pub. Date: Dec. 9, 2004

(54) Guide roller system for guiding the rods between the finishing stands of rod rolling mills

(76) Inventor: Otmar Palzer, Niederrieden (DE)

Correspondence Address: THE FIRM OF KARL F ROSS, 5676 RIVERDALE AVENUE, PO BOX 900, RIVERDALE (BRONX), NY, 10471-0900, US

(21) Appl. No.: 10/489,133

(22) PCT Filed: Aug. 21, 2002
(86) PCT No.: PCT/EP02/09334

(30) Foreign Application Priority Data
Sep. 6, 2001 (DE) 101436173

(51) Int. Cl. C30B 1/00

(52) U.S. Cl. 117/200

(57) ABSTRACT

The invention relates to a roller guide for the guidance of the wire or rod between the finish rolling mill stands of a wire or rod rolling line, comprised of a guide roller pair (FR1; FR2) which are mutually juxtaposed and journalled on the free ends of the pivot arms (SA1; SA2) of double arm levers (DH). The lever journals (HL) are connected with a support body between the finish mill rolls of the rolling line and which receives a centering funnel (ZT) for the rolled wire or rod between the double arm levers (DH) whereby the pivotal displacement of the pivot arms (SA1; SA2) are settable and spring adjustable about the lever journals. The roller guide is improved in that the pivot arms (SA1a; SA1b or SA2a; SA2b) have setting elements (SEa; SEb) pressed against the support body (TK) and in that an adjustable-pressure pneumatic spring (PF) is connected with the support body (TK) and bears upon the pivot arm (SA2b) extending away from the guide roller (FR2) or is connected with this pivot arm (SA2b) and pressed against the support body.

The invention relates to a roller guide system for guiding the wire or rod between the finish rolling mill stands of a wire or rod rolling line, comprised of a guide roller pair whose guide rollers, which are mutually juxtaposed with one another, are journaled on the free ends of respective pivot arms of double-arm levers, whose lever bearings [fulcra] are connected with a support body arranged between the finish rolling mill stands of the rolling line and which has, between the double-arm levers a centering funnel for the rolled wire or rod, whereby the pivotal displacement of the pivot arms about the lever bearing is spring-adjustable and settable.

Guide rolls of this type serve to permit the rolled wire or rod to be fed conveniently into the next pass of the rolling stands downstream of the guide rollers. The guide rollers are thus directed to the center of the pass and are positioned as close as possible to the rolls of the subsequent mill stand since apart from the high speeds with which the wire or rod of modern wire or rod rolling lines traverse the finished mill stands, in this section of the wire or rod rolling line, one must take into consideration narrow pass tolerances. The guide rollers must be able to engage as much as possible without play even oval shaped wire or rod cross sections in this part of the rolling line so as to prevent a tilting [twisting] of the wire or rod in the respective pass. This is achieved by a corresponding setting of the pivotal displacement of the pivot arms which carry the guide rollers, usually in the form of double-arm levers which are braced by leaf springs.

The most important drawback of this roller guide arrangement is that with the guide rollers set for a predetermined average cross sectional size of the wire or rod as a consequence of the unavoidable cross sectional variations of the rolled wire or rod which is fed between the rollers, elevated pressure loading of the guide rollers and the rolled wire or rod always arises when the wire cross section exceeds the preset dimensions. In these cases, the guide rollers work mainly as additional rolling elements. As a result, not only does the tolerances of the wire cross section suffer but the bearings of the guide rollers and the guide rollers themselves are loaded beyond the usual magnitudes.

In addition because the guides tend to loosen up, when the rolled wire or rod passing through them has cross sectional dimensions which exceed the set dimensions, there is the danger that the wire will tend to tip or twist in the guide pass. This is especially the case with oval cross sections as to which the tolerances also are poorer. In extreme cases, the rolled wire or rod can become over-rolled.

These problems are increased when the wire or rod is to be dimensionally rolled in accordance with the so-called “free size rolling” system since there the finished cross section of the rolled wire is maintained in a very narrow range and different torque cross sections are rolled in one and the same rolling pass. The invention has as its object to improve known roller guides so that the wire or rod guidance automatically matches the cross sectional variations which always arise.

This object is achieved in that on the pivot arms, respectively, between the guide rollers and the lever bearings, there are provided setting elements which are braced against the support body and an adjustable pressure pneumatic spring which is connected with the support body and bears against a pivot arm opposite the pivot arm provided with the guide roller or turned away from the pivot arm provided with the guide roller or connected with this pivot arm and braced against the support body.

It is also possible as the invention further foresees, to provide both of the pivot arms turned away from the guide rollers, each with a pneumatic spring braced against the support body.

The pneumatic springs, which, upon displacement of the levers within a fixed range, counteract this displacement [shifting] always with constant force and thereby ensure that a rolled wire or rod guide thus equipped can feed different wire or rod cross sections into the rolling pass such that both the rolled wire or rod and also the guide rollers will be impacted always with a constant pressure, independently of the size of the fed cross section. The rolled wire or rod is, as a result of this adapted roller guidance, fed without play and with a constant force, independently of cross sectional variations and does not require, within a certain wire or rod cross sectional range any resetting for each wire cross section, with the consequence that there is a saving in time in rolling mill operations and a corresponding reduction in the operating costs. Apart from the better adherence to tolerances, which results, there is also an increase in the useful life of the guide rollers and their bearings and this contributes to further reduction in cost.

The invention is described in greater detail in conjunction with the embodiments shown in the drawing. In the drawing there is shown in:

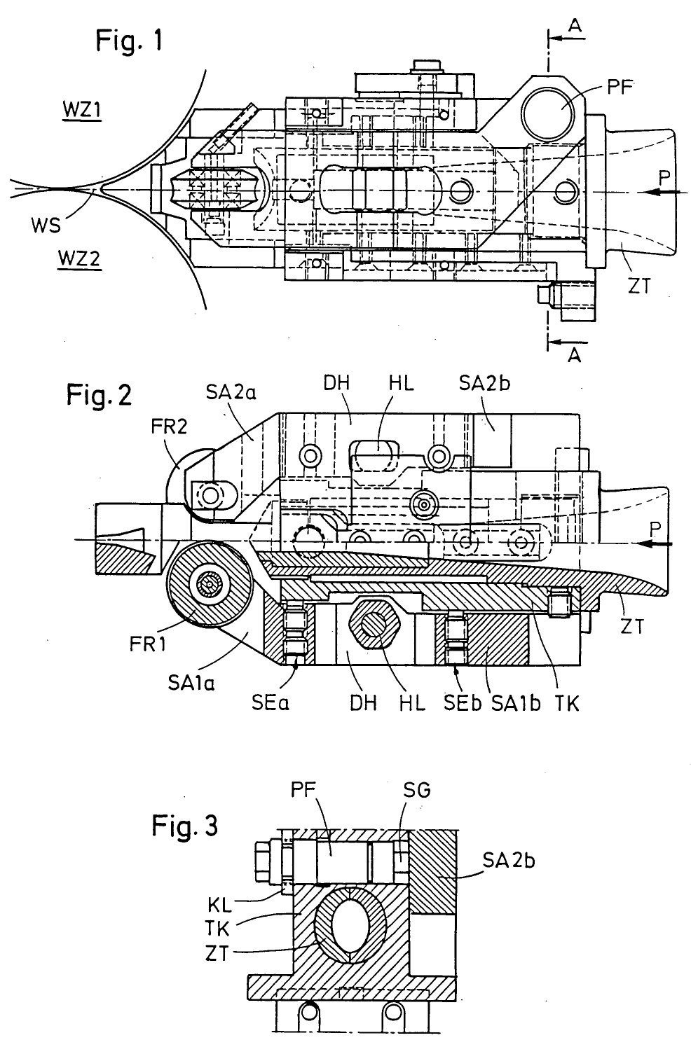

FIG. 1 the elevation of a longitudinal section through the roller guide,

FIG. 2 the plan view of FIG. 1, partly in section,

FIG. 3 an elevation of the section taken along the line A-A of FIG. 1,

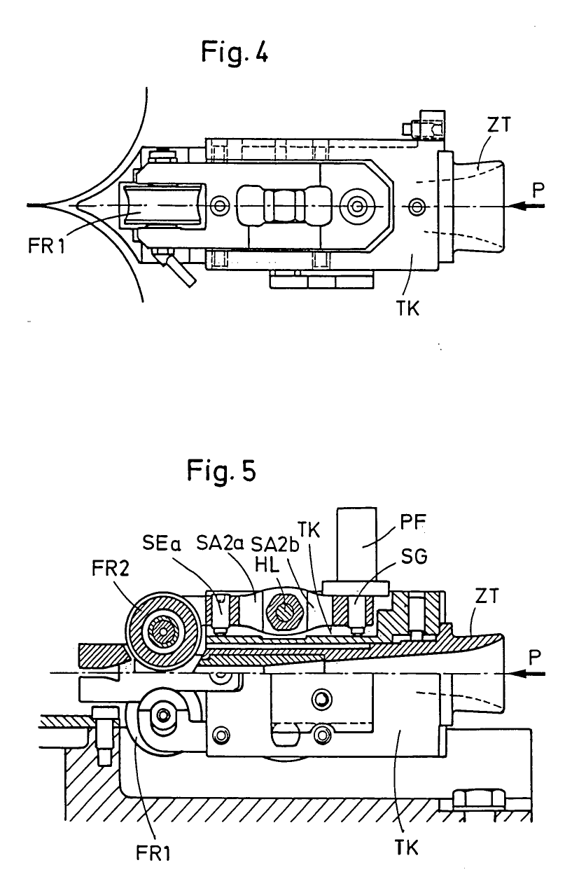

FIG. 4 the elevation of another embodiment of the roller guide; and

FIG. 5 the plan view of FIG. 4, partly in section.

As can be seen from FIGS. 1 and 2, the roller guide which is located directly ahead of the rolling gap WD formed by the two mill rolls WZ1, WZ2, is comprised of a support body TK which is connected with the rolling mill frame in a manner not shown and which enables the roller guide to be directed to [aligned with] this rolling gap WS. On opposite sides of a centering funnel ZT carried by the carrier body and through which a rolled wire or rod, not shown, is fed in the direction of the arrow, are respective double-arm levers DH journaled in respective lever bearings HL.

The pivot arms SA1a and SA2a of the double levers DH which are juxtaposed with the rolls WL1 [sic] and WL2 [sic], carry the two guide rollers FR1 and FR2 and the pivot arms SA1b and SA2b extending away from these guide rollers have respective setting elements SEa and SEb braced against the support body TK.

On the support body TK there is further (see FIG. 3), above the centering funnel ZT, a pneumatic spring PL with a setting member SG which here bears against the pivot arm SA2b extending away from guide roller FR2. The pneumatic spring PF is fitted in a corresponding receiving opening in the carrier body TK and is secured in it with a clamping device KL.

With the roller guide according to FIGS. 4 and 5 whose configuration correspond to the configuration according to FIGS. 1-3 except for the arrangement of the pneumatic spring, this pneumatic spring PF is not, as in FIGS. 1-3, connected with the support body TK but rather is mounted on the pivot arm SA2b extending away from the guide roller FR2. The setting member SG of the pneumatic spring PF here is braced against the support body TK.

The roller wire or rod, for example with an oval cross section, is fed from the centering funnel ZT through the guide gap formed by the guide rollers FR1 and FR2. This guide gap is set with the aid of setting elements SEa, SEb and indeed such that the gap width is by an offset smaller than the setpoint cross section of the rolled wire or rod. In conjunction with thin setting, the pneumatic springs PF are slid into the receiving opening of the support body TK and secured in place with the clamping devices KL. The profile of the lowered wire or rod which enters the feed or guide gap opens this gap against the pressure of the pneumatic spring PF by an amount corresponding to the actual cross section. The pneumatic spring PF thus insures that the guide rollers FR1, FR2 are preset with a spring force as established in this pneumatic spring. This spring force is so dimensioned that the guide rollers FR1, FR2 bear upon the rolled wire or rod, independently of changes in the diameter of the rolled wire or rod segment traversing the guide, always with the same pressure. The spring force of the pneumatic spring PF is thus so dimensioned that the rolled wire or rod is reliably fed between the guide rollers FR1, FR2 but not rolled reduced in cross section thereby.

Reference character list

| | |
|---|---|
| FR1 | Guide Roller |
| FR2 | Guide Roller |
| SA1a | Pivot Arm |
| SA2b | Pivot Arm |
| SA2a | Pivot Arm |
| SA2b | Pivot Arm |
| DH | Double Arm Lever |
| HL | Lever Journal [Fulcrum] |
| TK | Support Body |
| ZT | Centering Funnel |
| SEa | Setting Element |
| SEb | Setting Element |
| PF | Pneumatic Spring |
| WZ1 | Roll |
| WZ2 | Roll |
| WS | Rolling Gap |
| SG | Setting Body |
| KL | Clamping Device |
| P | Arrow |

1. A roller guide for the guidance of wire or rod between the finished rolling mills of a wire or rod rolling line, comprised of a pair of guide rollers whose guide rollers (FR1; FR2) are opposite one another and journalled on the free ends of the pivot arms (SA1; SA2) of double arm levers (DH) whose lever journals (HL) are connected with a support body (TK) between in finish rolling mill stands of the rolling line and in which between the double arm levers (DH) a centering funnel (ZT) for the rolled wire or rod is received by the support body (TK), whereby the pivotal displacement of the pivot arms (SA1; SA2) are spring adjustable and settable, characterized in that setting elements (SEa; SEb) are provided on the pivot arms (SA1a; SA1b or SA2a; SA2b) and press against the support body (TK) and an adjustable pressure spring pneumatic (PF) is connected with the support body (TK) and pressed against the pivot arm (SA2b) extending away from the guide roller (FR2) or is connected with this pivot arm (SA2b) and braced against the support body (TK).
